(19) United States
(12) Patent Application Publication
(10) Pub. No.: US 2012/0118505 A1
(43) Pub. Date: May 17, 2012

(54) PLASMA PROCESSING APPARATUS AND COOLING DEVICE FOR PLASMA PROCESSING APPARATUS

(75) Inventor: Kiyotaka Ishibashi, Hyogo (JP)

(73) Assignee: TOKYO ELECTRON LIMITED, Tokyo (JP)

(21) Appl. No.: 13/379,219

(22) PCT Filed: May 20, 2010
(86) PCT No.: PCT/JP2010/058499

§ 371 Date: Jan. 23, 2012

(30) Foreign Application Priority Data
Jun. 19, 2009 (JP) 2009-146838

(51) Int. Cl. H01L 21/3065; C23C 16/511

(52) U.S. Cl. 156/345.37; 118/723 AN

(57) ABSTRACT

A coolant flow path for cooling a dielectric window of a side wall of a processing container of the plasma processing apparatus is provided. A coolant flows in a liquid or gaseous state in the coolant flow path without phase transition. At least a portion of the coolant flow path extending in a circumferential direction of the side wall has a cross-sectional area decreased toward downstream from upstream.

### TECHNICAL FIELD

The present invention relates to a plasma processing apparatus for performing plasma processing on an object to be processed such as a semiconductor wafer, a substrate for liquid crystals, or an organic electroluminescent (EL) device.

### BACKGROUND ART

Recently, a semiconductor device widely used is required to have higher speed operation and lower power consumption. In order to meet the requirements, the semiconductor device needs to be highly integrated and miniaturized. As the semiconductor device is highly integrated and miniaturized, an apparatus for manufacturing the semiconductor device is required to process fine structures on a semiconductor substrate with small damage.

As a plasma processing apparatus for performing processing with small damage, a microwave plasma processing apparatus which may generate plasma having a low electron temperature and a high density has drawn attention. In a microwave plasma processing apparatus used to etch a semiconductor substrate or form a film, a radial line slot antenna (RLSA) which is a planar antenna for uniformly generating plasma by uniformly introducing a microwave into a processing container is generally used. According to the RLSA, since a microwave may be uniformly supplied into the processing container, a semiconductor substrate may be uniformly processed in a plane. In addition, plasma having a high density may be generated in a wide area under the antenna. Also, since plasma having a low electron temperature may be generated, damage to a semiconductor substrate may be reduced.

The RLSA is connected to a coaxial waveguide which propagates a microwave. A microwave supplied from the coaxial waveguide propagates in a radial direction in a dielectric plate having a disc shape in the antenna. A wavelength of the microwave is compressed in the dielectric plate and the microwave having the compressed wavelength is radiated into a processing container through slots of a slot plate closely contacting a bottom portion of the dielectric plate. Due to an electric field of the microwave in the processing container, a plasma exciting gas in the processing container is excited to be in a plasma state.

The planar antenna is heated mainly by plasma during a process. When the planar antenna is heated, since the planar antenna is deformed due to a difference in thermal expansion coefficients between elements of the planar antenna, propagation characteristics of the microwave may be changed. The microwave propagates in a radial direction in the dielectric plate, which may be formed of alumina or the like, to form a standing wave, and is supplied into the processing container through the slots of the slot plate, which may be formed of copper or the like. When positions of the slots formed in the slot plate having a high thermal expansion coefficient are changed, since the microwave in the dielectric plate is disturbed, a propagation state of the microwave supplied into the processing container is changed. In this case, a plasma state excited by the microwave in the processing container is also changed. In particular, if the processing apparatus is large, an extent to which positions of the slots are changed due to a difference in thermal expansion coefficients is increased.

In order to prevent a planar antenna heated by plasma from being deformed, a cooling device in which a cooling jacket is provided on a planar antenna and a coolant flows in a coolant flow path of the cooling jacket to cool the planar antenna is disclosed in Patent Document 1.

[Patent Document 1] Japanese Laid-Open Patent Publication No. 2007-335346

### DISCLOSURE OF THE INVENTION

### Technical Problem

However, in a conventional cooling device, since a coolant flowing in a coolant flow path is gradually heated, a temperature of the coolant at an inlet of the coolant flow path and a temperature of the coolant at an outlet of the coolant flow path are different from each other, and thus an amount of heat transferred to the coolant from a wall surface of the coolant flow path is not uniform. The amount of transferred heat is proportional to a temperature difference between the wall surface of the coolant flow path and the coolant. Accordingly, when the temperature of the coolant at the inlet and the temperature of the coolant at the outlet are different from each other, the temperature difference at the inlet and the temperature difference at the outlet are different from each other and thus the amount of transferred heat at the inlet and the amount of transferred heat at the outlet are different from each other.

In order to uniformly cool a planar antenna, in the conventional cooling device, one coolant flow path is folded at a middle point so that a front half of the coolant flow path and a front half of the coolant flow path are disposed adjacent to each other. When the coolant flow path is disposed in this way, an amount of heat transferred through the front half of the coolant flow path and an amount of heat transferred through the back half of the coolant flow path may be similar to each other.

However, when the coolant flow path is folded, a specific portion of the planar antenna may be uniformly cooled, but it is difficult to uniformly cool an entire circumferential portion of the planar antenna. Also, when the coolant flow path is folded, an amount of space which the coolant flow path fills is increased, thereby making it difficult to provide the coolant flow path in a narrow side wall of a processing container.

A recent microwave plasma processing apparatus for processing a semiconductor substrate which has a large diameter of 300 mm instead of 200 mm is required to not change a propagation state of a microwave of a planar antenna, as compared to a conventional apparatus. In order to meet the requirement, a cooling device is required to more uniformly cool the planar antenna.

Accordingly, an objective of the present invention is to provide a plasma processing apparatus and a cooling device for a plasma processing apparatus which may uniformly cool a planar antenna or a dielectric window in a circumferential direction.

### Technical Solution

In order to solve the above and other problems, according to an aspect of the present invention, there is provided a plasma processing apparatus including: a processing container which is sealable and in which plasma processing is performed on an object; a holding stage which is disposed in the processing container and holds the object; a dielectric window which is disposed on a ceiling portion of the processing container and seals the processing container; and a microwave antenna which is disposed on the dielectric window and radiates a microwave into the processing container, wherein a coolant flow path for cooling the dielectric window is provided in a side wall of the processing container, a coolant flows in a liquid or gaseous state in the coolant flow path without phase transition, and at least a portion of the coolant flow path elongated in a circumferential direction of the side wall has a cross-sectional area decreased toward downstream from upstream.

According to another aspect of the present invention, there is provided a plasma processing apparatus including: a processing container which is sealable and in which plasma processing is performed on an object; a holding stage which is disposed in the processing container and holds the object; a dielectric window which is disposed on a ceiling portion of the processing container and seals the processing container; a microwave antenna which is disposed on the dielectric window and radiates a microwave into the processing container; and a cooling plate which is disposed on the microwave antenna and includes a coolant flow path for cooling the microwave antenna, wherein a coolant flows in a liquid or gaseous state in the cooling plate without phase transition, and at least a portion of the coolant flow path extending in a circumferential direction of the cooling plate has a cross-sectional area decreased toward downstream from upstream.

According to another aspect of the present invention, there is provided a plasma processing apparatus including: a processing container which is sealable and in which plasma processing is performed on an object; a holding stage which is disposed in the processing container and holds the object; a plasma exciting unit which excites plasma in the processing container; and a coolant flow path which cools a member heated by the plasma, wherein a coolant flows in a liquid or gaseous state in the coolant flow path without phase transition, and at least a portion of the coolant flow path has a cross-sectional area decreased toward downstream from upstream.

According to another aspect of the present invention, there is provided a cooling device for a plasma processing apparatus which is provided in the plasma processing apparatus for performing plasma processing on an object and cools a member heated by plasma, the cooling device including a coolant flow path in which a coolant flows in a liquid or gaseous state without phase transition, wherein at least a portion of the coolant flow path has a cross-sectional area decreased toward downstream from upstream.

### Advantageous Effects

An amount of heat transferred to a coolant from a wall surface of a coolant flow path is defined by Q=hA(T_{w}−T₀), where h denotes a heat transfer rate, A denotes a heat transfer area, and (T_{w}−T₀) denotes a temperature difference between the coolant and the wall surface

When a cross-sectional area of the coolant flow path is reduced, a flow velocity of the coolant is increased, and thus the heat transfer rate h is increased. When a cross-sectional area of a coolant flow path is decreased toward downstream from upstream as in the present invention, since a decrement in a temperature difference as a temperature of a coolant is increased may be compensated by an increment in the heat transfer rate h, an amount of heat transferred in the coolant flow path in a longitudinal direction may be maintained almost constant. Accordingly, a planar antenna or a dielectric window may be uniformly cooled in a circumferential direction.

### BRIEF DESCRIPTION OF THE DRAWINGS

FIG. 1 is a view showing an overall configuration of a plasma processing apparatus according to an embodiment of the present invention.

FIG. 2 is a view showing a coolant flow path formed in an upper plate according to an embodiment of the present invention (FIG. 2A is a plan view and FIG. 2B is a cross-sectional view).

FIG. 3 is a graph showing a relationship between a groove height and an azimuth of a coolant flow path (FIG. 3A shows a case where the coolant flow path turns three times and FIG. 3B shows a case where the coolant flow path turns three times).

FIG. 4 is a view showing a coolant flow path formed in an upper plate according to another embodiment of the present invention (FIG. 4A is a plan view and FIG. 4B is a cross-sectional view).

FIG. 5 is a graph (third-degree expression) showing a relationship between a groove height and an azimuth of a coolant flow path.

FIG. 6 is a view showing a coolant flow path formed in a cooling plate (FIG. 6A is a cross-sectional view and FIG. 6B is a plan view).

FIG. 7 is a graph showing results obtained after calculating a heat transfer line density in a conventional example and an example of the present invention;

FIG. 8 is a graph showing a dependence of a difference in a heat transfer line density on a flow rate.

FIG. 9 is a graph showing a relationship between a groove height and an azimuth when a height of a coolant flow path is defined as a third-degree expression of a path length.

FIG. 10 is a graph showing a relationship between a heat transfer rate distribution per unit length and an azimuth when a height of a coolant flow path is defined as a third-degree expression of a path length.

FIG. 11 is a graph showing a relationship between a flow rate and uniformity when a height of a coolant flow path is defined as a third-degree expression of a path length.

FIG. 12 is a view showing a coolant flow path having two paths formed in an upper plate according to another example of the present invention (FIG. 12A is a plan view and FIG. 12B is a cross-sectional view).

FIG. 13 is a graph showing a relationship between a groove height of each of first and second coolant flow paths and an azimuth.

FIG. 14 is a graph showing a relationship (in a comparative example) between a heat transfer rate distribution per unit length and an azimuth, when a groove height of each of coolant flow paths is constant.

FIG. 15 is a graph showing a relationship (in an example of the present invention) between a heat transfer rate distribution per unit length and an azimuth, when a groove height of each of coolant flow paths is changed.

FIG. 16 is a graph showing a relationship between a flow rate and uniformity when a groove height of each of coolant flow paths is changed.

### EXPLANATION ON REFERENCE NUMERALS

100: processing container

105: dielectric window

115: holding stage

140: upper plate (side wall of processing container, cooling device)

145: coolant flow path

145a: first coolant flow path

145b: second coolant flow path

210: cooling plate (cooling device)

905: planar antenna (microwave antenna, plasma exciting unit)

910: upper cover

915: coolant flow path

U: processing space

W: wafer (substrate to be processed)

### BEST MODE FOR CARRYING OUT THE INVENTION

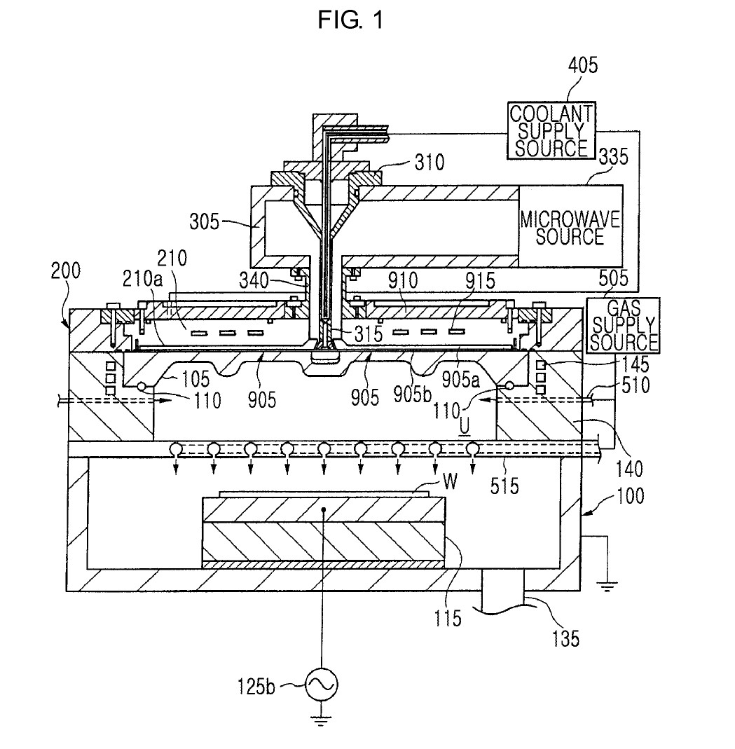

A plasma processing apparatus according to an embodiment of the present invention will now be explained with reference to the attached drawings. FIG. 1 shows an overall configuration of the plasma processing apparatus.

A processing container 100 having a substantially cylindrical shape is formed of aluminum or stainless steel containing aluminum. A protection coating film such as an aluminum oxide (alumina) coating film or an Yttria (Y₂O₃) coating film is formed on an inner wall surface of the processing container 100.

A dielectric window 105 which seals the processing container 100 and through which a microwave is transmitted is provided on a ceiling portion of the processing container 100 with a sealing member 110 therebetween. The dielectric window 105 is formed of quartz or ceramic (such as alumina or aluminum nitride). The dielectric window 105 is fixed to the processing container 100 by using a fixing ring 200 disposed on an upper portion of a side wall of the processing container 100.

A gas introduction unit 510 through which a process gas is introduced into a processing space U is provided in the side wall of the processing container 100. In the present embodiment, the processing space U is divided into two areas by a lower shower 515, and a plasma exciting gas such as an argon gas or a krypton gas is introduced from the gas introduction unit 510 disposed over the lower shower 515 and a process gas is introduced from the lower shower 515. The gas introduction unit 510 and the lower shower 515 are connected to a gas supply source 505. Alternatively, the lower shower 515 may not be provided, and a plasma exciting gas, a process gas, and a cleaning gas may be optionally introduced from the gas introduction unit 510. If the lower shower 515 is not provided, an upper portion (hereinafter, referred to as an upper plate 140) of the side wall of the processing container 100 divided by the lower shower 515 is integrally formed with the side wall. Also, the gas introduction unit 510 having a shower head shape may be provided in the ceiling portion of the processing container 100.

A coolant flow path 145 for cooling the dielectric window 105 is provided in the upper plate 140, which serves as a cooling device. A fluorine-based liquid having high electrical insulating characteristic and high thermal conductivity flows as a coolant in the coolant flow path 145. While the coolant flows in the coolant flow path 145, the coolant flows in a liquid state in the coolant flow path 145 without phase transition. When the dielectric window 105 is cooled by using the upper plate 140, a temperature of the upper plate 140 may be equal to or lower than 90° C. (a target temperature ranges from 70 to 80° C.) and a temperature of the dielectric window 105 may be equal to or lower than 150° C. A structure of the coolant flow path 145 will be explained below.

An inlet/outlet (not shown) through which a substrate to be processed is transferred is provided in a lower portion of the side wall of the processing container 100 divided by the lower shower 515. The inlet/outlet is opened and closed by a gate valve.

An exhaust port 135 for depressurizing the processing container 100 through vacuum suction is formed at a bottom of the processing container 100. The exhaust port 135 is connected to an exhaust device (not shown).

A holding stage 115 on which a wafer W, which is the substrate to be processed, is held is provided in the processing container 100. A high frequency power supply 125b for applying a bias to adsorb the wafer W by using an electrostatic force is connected to the holding stage 115.

A planar antenna 905 which has a disc shape and serves as a microwave antenna for exciting plasma by supplying a microwave into the processing space U is disposed on the dielectric window 105. The planar antenna 905 includes a slot plate 905b having two types of slots perpendicular to each other, and a dielectric plate 905a provided between the slot plate 905b and a conductive surface 210a which reflects a microwave. The planar antenna 905 is also called a radial line slot antenna (RLSA). The planar antenna 905 is fixed to the processing container 100 by using an antenna fixing unit. A microwave generated by a microwave source 335 propagates in a transverse electric (TE) mode through a rectangular waveguide 305, passes through a coaxial converter 310, and propagates in a transverse electromagnetic (TEM) mode in a coaxial waveguide 340. The coaxial waveguide 340 is connected to a center of the planar antenna 905. The microwave introduced from the center of the planar antenna 905 propagates in a radial direction through the dielectric plate 905a, in which a wavelength of the microwave is compressed, and is emitted into the processing space U from the slots formed in the slot plate 905b. A conductor of the coaxial waveguide 340 is cooled by a coolant supplied from a coolant supply source 405.

A cooling plate 210 which serves as a cooling device for cooling the planar antenna 905 is provided on the conductive surface 210a. The cooling plate 210 may be integrally formed with the conductive surface 210a. A coolant flow path 915 for cooling the planar antenna 905 is formed over the conductive surface 210a. A fluorine-based liquid having high electrical insulating characteristic and high thermal conductivity flows as a coolant in the coolant flow path 915. While the coolant flows in the coolant flow path 915, the coolant flows in a liquid state in the coolant flow path 915 without phase transition. When the planar antenna 905 is cooled by using the cooling plate 210, a temperature of the cooling plate 210 may be in a range of 110 to 120° C. and a temperature of the planar antenna 905 may be in a range of 150 to 160° C. A configuration of the coolant flow path 915 of the cooling plate 210 will be explained below.

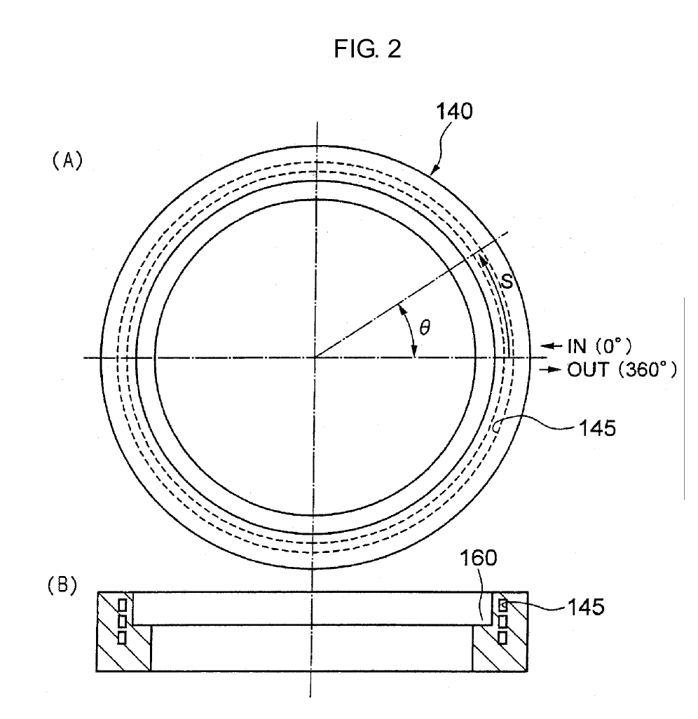

FIG. 2 shows the upper plate 140. The upper plate 140 has an annular shape, and a receiving portion 160 on which the dielectric window 105 is placed is formed on an upper portion of an inner circumference of the upper plate 140. The coolant flow path 145 extending in a circumferential direction is formed in the upper plate 140. The coolant flow path 145 is formed to have a spiral shape turning one or more times. The coolant flow path 145 has one inlet and one outlet. An azimuth of the inlet and an azimuth of the outlet when the upper plate 140 is seen from a plane are almost the same. When an XY coordinate system is used as shown in FIG. 2A, an azimuth of the inlet is 0° and an azimuth of an outlet is 360°. The coolant flow path 145 has a rectangular cross-sectional shape. A width of the coolant flow path 145 is not changed irrespective of a path length of the coolant flow path 145. Meanwhile, a height of the coolant flow path 145 is decreased toward downstream from upstream. Also, a length measured from the inlet of the coolant flow path 145 is referred to as a path length s and an azimuth at the path length s is denoted by ⊖.

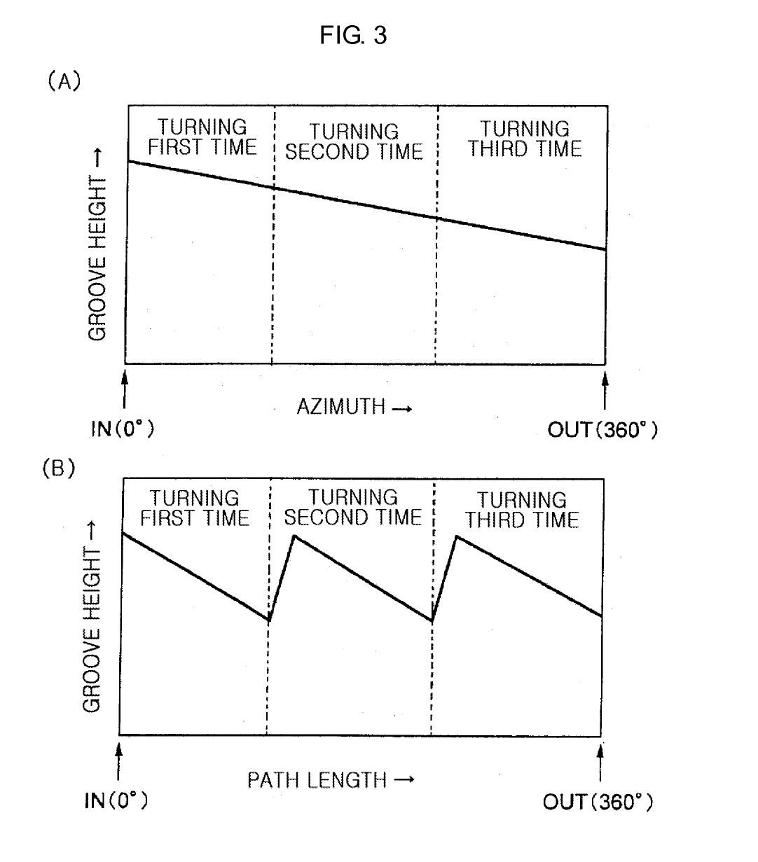

FIG. 3A shows an example of a change in a height when the coolant flow path 145 turns three times. In FIG. 3A, the height (a groove height) of the coolant flow path 145 is linearly reduced toward the outlet from the inlet. The width of the coolant flow path 145 is not changed and thus constant. Accordingly, a cross-sectional area of the coolant flow path 145 is decreased toward the outlet from the inlet.

FIG. 3B shows another example of a change in a height when the coolant flow path 145 has a spiral shape turning three times. In FIG. 3B, a height of a portion of the coolant flow path 145 turning one time is decreased as an azimuth changes from 0° to about 360°. At a connected portion between a portion of the coolant flow path 145 turning one time and another portion of the coolant flow path 145 turning one time (for example, a connected portion between a portion of the coolant flow path 145 turning a first time and a portion of the coolant flow path 145 turning a second time), the height of the coolant flow path 145 is increased to an original height. That is, a height of the portion of the coolant flow path 145 turning the first time, located at an upper stage, a height of the portion of the coolant flow path 145 turning the second time, located at a middle stage, and a height of a portion of the coolant flow path 145 turning a third time, located at a lower stage, are the same if azimuths are the same.

The coolant flow path 145 may be formed such that a plurality of the coolant flow paths 145 each having a doughnut shape turning one time are vertically arranged instead of a spiral shape. In this case, each coolant flow path 145 turning one time has an inlet and an outlet. Each coolant flow path 145 turning one time has a constant width and a height decreased toward the outlet from the inlet. A height of the coolant flow path 145 turning a first time located at an upper stage, a height of the coolant flow path 145 turning a second time located at a middle stage, and a height of the coolant flow path 145 turning a third time located at a lower stage are the same when azimuths are the same.

When the coolant flow path 145 is actually formed, the upper plate 140 is vertically divided into a plurality of portions according to a number of times the coolant flow path 145 turns. A groove constituting the coolant flow path 145 is formed in each of the plurality of portions of the upper plate 140. The groove of the coolant flow path 145 is formed by using a numerically controlled (NC) lathe using a tool such as an endmill. When the groove of the coolant flow path 145 is formed via cutting process by using the tool, since a cutting depth of the tool may be controlled through numerical control, it is easier to change a depth (a height) of the groove instead of changing a width of the groove. As shown in FIG. 3A, the height of the coolant flow path 145 is in a linear relationship with the path length of the coolant flow path 145, and when the path length is s and the height of the coolant flow path 145 is d, d=a·s, where a is an integer. When a first-degree expression is input as a cutting depth of the tool to the NC lathe, the height of the coolant flow path 145 may be changed linearly.

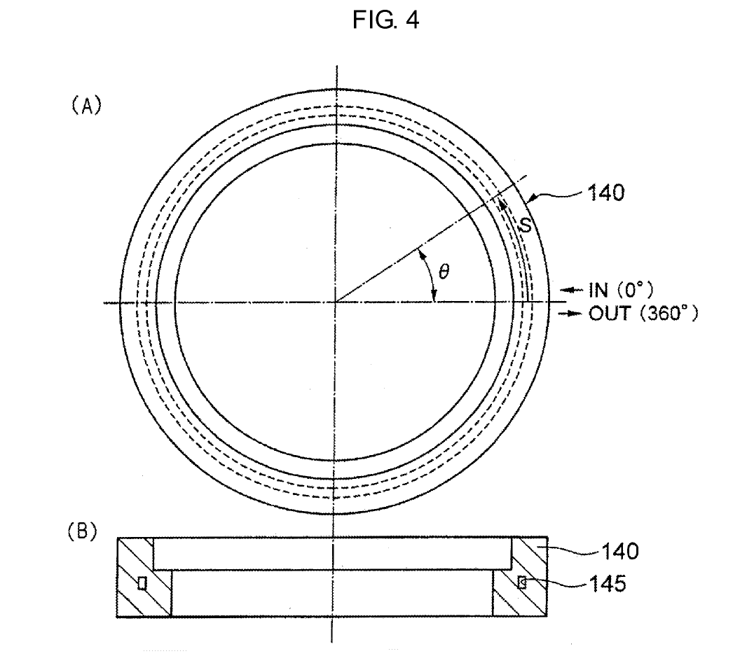

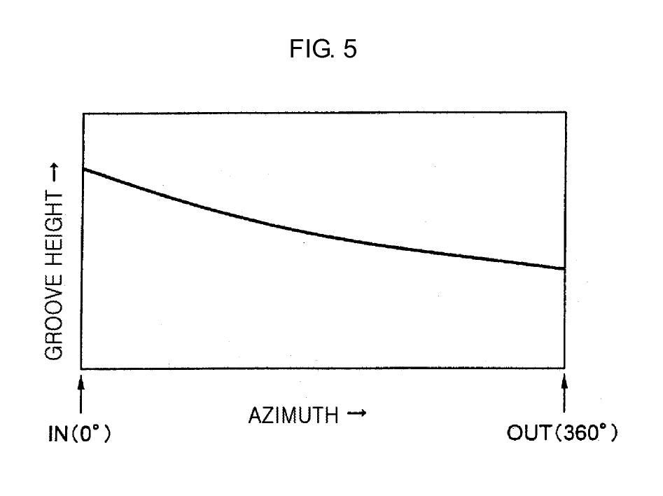

FIG. 4 shows the coolant flow path 145 formed in the upper plate 140 according to another embodiment of the present invention. In the present embodiment, the coolant flow path 145 turning one time is formed in the upper plate 140. The inlet of the coolant flow path 145 has an azimuth of 0° and the outlet of the coolant flow path 145 has an azimuth of 360°. As shown in FIG. 5, the height of the coolant flow path 145 is decreased from the inlet to the outlet and is defined as a third-degree expression of the path length s. The width of the coolant flow path 145 is constant. As such, the height d of the coolant flow path 145 may be decreased from the inlet to the outlet and may be defined as a second- or third-degree expression of the path length s.

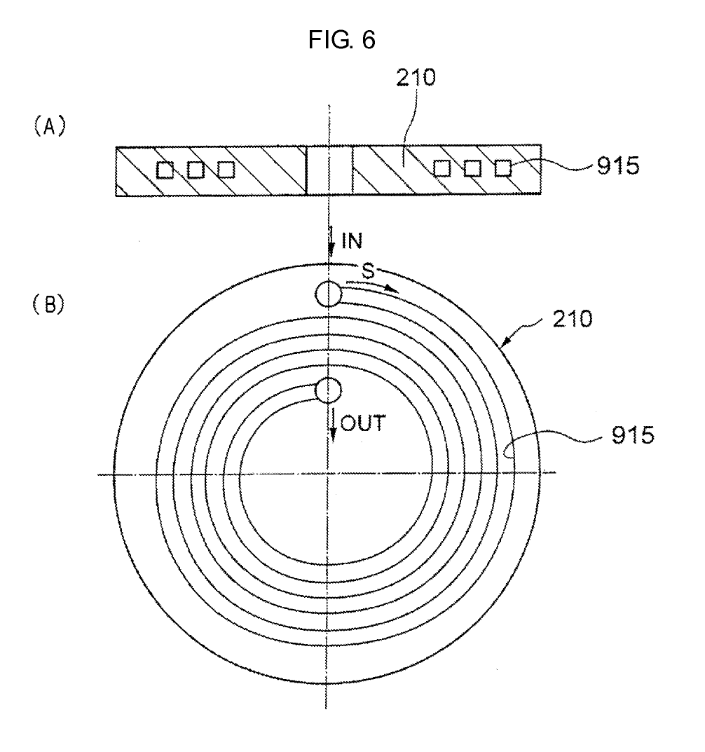

FIG. 6 shows the coolant flow path 915 formed in the cooling plate 210. The coolant flow path 915 having a spiral shape is formed in the cooling plate 210 having a circular disc shape. The coolant flow path 915 having the spiral shape may turn one or more times. Azimuths of an inlet and an outlet of the coolant flow path 915 are the same. The inlet may be formed at an outer circumference of the coolant flow path 915 and the outlet may be formed at an inner circumference of the coolant flow path 915, or the inlet may be formed at the inner circumference of the coolant flow path 915 and the outlet may be formed at the outer circumference of the coolant flow path 915. The coolant flow path 915 has a rectangular cross-sectional shape. A height of the coolant flow path 915 is decreased toward the outlet from the inlet. Meanwhile, a width of the coolant flow path 915 is not changed. The height of the coolant flow path 915 is defined as an nth-degree expression of a path length s. Also, the height is decreased toward downstream from upstream while the coolant flow path 915 turns one time, and the height of the coolant flow path 915 at a joint between a portion of the coolant flow path 915 turning one time and another portion of the coolant flow path 915 turning one time may return to an original height.

Since a cross-sectional area of each of the coolant flow paths 145 and 915 is decreased toward downstream from upstream, an amount of heat transferred in each of the coolant flow paths 145 and 915 may be maintained constant. A causal relationship between ‘decreasing a cross-sectional area of a coolant flow path’ and ‘maintaining an amount of transferred heat constant’ is as follows.

An amount of heat Q transferred to a coolant from a wall surface of a coolant flow path is defined by the following equation.

Q=hA(T_{w}−T₀) [Equation 1]

In Equation 1, “Q” denotes an amount of transferred heat (W), “h” denotes a heat transfer rate (W/m²K), “A” denotes a heat transfer area (m²), “T_{w}” denotes a temperature of a surface of a wall surface (K), and “T₀” denotes a temperature of a coolant (K).

Since a temperature of a coolant is gradually increased toward downstream from upstream due to heat exchange, in order to maintain an amount of transferred heat constant and a temperature of a wall surface constant in a coolant flow path, a heat transfer rate needs to be increased toward the downstream from the upstream. The heat transfer rate h is defined by Equation 2.

h=Nuk/L [Equation 2]

In Equation 2, “Nu” denotes a Nusselt number, “k” denotes a thermal conductivity (W/m²K), and “L” denotes a length of a flow path.

Since the thermal conductivity k of a fluid and the length of the flow path L are constant, in order to increase h, the Nusselt number Nu needs to be increased.

The Nusselt number Nu is defined by Equation 3.

Nu=0.664Re^{1/2}Pr^{1/3}

Re=UL/v [Equation 3]

In Equation 3, “Pr” denotes a Prandtl number, “U” denotes a flow velocity (m/s), and “v” denotes a kinematic viscosity coefficient (m²/s).

Since the kinematic viscosity coefficient v is constant, the Nusselt number Nu may be increased by increasing the flow velocity U. When a cross-sectional area of a coolant flow path is decreased toward downstream from upstream, a flow velocity is increased. Accordingly, the Nusselt number Nu is increased in Equation 3, and the heat transfer rate h is increased in Equation 2. When a cross-sectional area of a coolant flow path is decreased toward downstream from upstream, the heat transfer area A of Equation 1 is reduced. However, an increment in the heat transfer rate h may be greater than a decrement in the heat transfer area A. As a result, the amount of transferred heat Q of Equation 1 may be maintained constant.

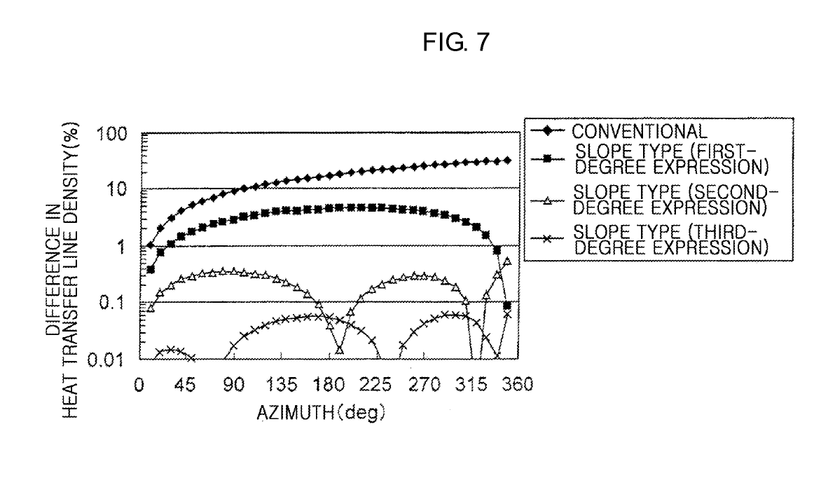

FIG. 7 shows results obtained after calculating an amount of transferred heat (a heat transfer line density) per unit length in a conventional example and an example of the present invention. The conventional example and the example of the present invention were compared under conditions: a width of a coolant flow path is 8 mm, a height of a portion of the coolant flow path at an inlet is 9 mm, a value obtained by subtracting a temperature of a coolant from a temperature of an upper plate is 20° C., and an amount of transferred heat is 2 kW.

Table 1 shows main conditions of results of the calculation.

TABLE 1

| | Conventional | | | |
|---|---|---|---|---|
| | example | Slope type | | |
| | (depth is | First-degree | Second-degree | Third-degree |
| | constant) | expression | expression | expression |
| Flow rate | 10.9 | 8.0 | 9.0 | 8.9 |
| (L/m) | | | | |
| Pressure | 0.024 | 0.053 | 0.061 | 0.060 |
| (MPa) | | | | |
| Minimum Re | 3.1e+4 | 2.6e+4 | 2.5e+4 | 2.5e+4 |
| Uniformity | 36.2 | 4.6 | 0.7 | 0.1 |
| of amount of | | | | |
| transferred | | | | |
| heat | | | | |
| (Max-Min)/ | | | | |
| average (%) | | | | |

As shown in Table 1, when a cross-sectional area of a coolant flow path is constant as in the conventional example, a difference in a heat transfer line density between an inlet and an outlet of the coolant flow path is about 40%. However, when a height of a coolant flow path is decreased, a difference in a heat transfer line density may be reduced to 4.6% (in the first-degree expression), 0.7% (in the second-degree expression), and 0.1% (in the third-degree expression).

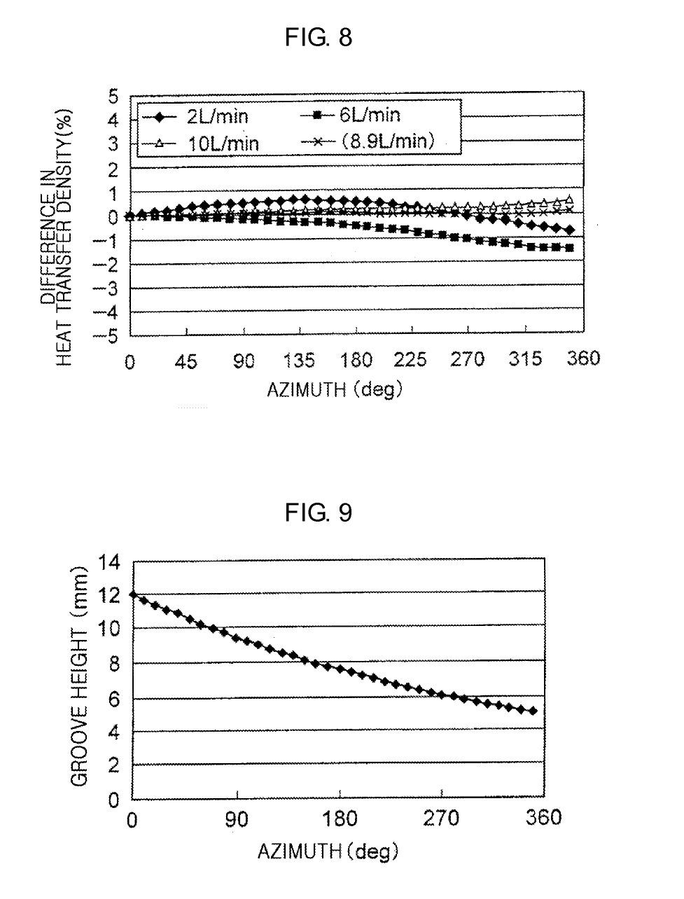

Next, how a difference in a heat transfer line density is affected by a change in a flow rate (that is, a dependence of a difference in a heat transfer line density on a flow rate) was calculated. Calculation conditions of the third-degree expression where a difference in a heat transfer line density is the lowest were used. That is, the calculation was made under conditions: a width of a coolant flow path is 8 mm, a height of a portion of the coolant flow path at an inlet is 9 mm (a height is reduced in a third-degree expression manner toward downstream), a value obtained by subtracting a temperature of a coolant from a temperature of an upper plate is 20° C., and an amount of transferred heat is 2 kW. Results of the calculation are shown in FIG. 8, and main conditions of the results of the calculation are shown in Table 2.

TABLE 2

| | 2 L/min | 6 L/min | 10 L/min |
|---|---|---|---|
| Flow rate (L/m) | 2 | 6 | 10 |
| Pressure (MPa) | 0.004 | 0.030 | 0.074 |
| Minimum Re | 5.6e+3 | 1.7e+4 | 2.8e+4 |
| Total amount of | 0.48 | 1.38 | 2.22 |
| transferred heat | | | |
| (kW) | | | |
| Uniformity of | 1.3 | 1.1 | 0.5 |
| amount of | | | |
| transferred heat | | | |
| (Max-Min)/average | | | |
| (%) | | | |

While a temperature distribution is changed according to a flow rate of a coolant, since a difference in a heat transfer line density is about 2% in a range, the difference in the heat transfer line density hardly depends on the flow rate of the coolant.

Table 3 shows results obtained after calculating how a difference in a heat transfer line density is affected by a structure of a coolant flow path (a dependence of a difference of a heat transfer line density on a structure of a coolant flow path).

TABLE 3

| | | | Amount | | | | |
|---|---|---|---|---|---|---|---|
| | | | of | | | | |
| | | Depth of | transferred | Flow | | | Uniformity of amount |
| | | outlet | heat | rate | Minimum | Pressure | of transferred heat |
| Structure | | (mm) | (kW) | (L/min) | Re | (MPa) | (Max-Min)/average (%) |
| Conventional | 9 × 8 × 1 turn | 9 | 2 | 10.9 | 3.1e+4 | 0.024 | 36.2 |
| example | 9 × 8 × 2 turn | | 2 | 6.2 | 1.7e+4 | 0.018 | 7.4 |
| | (reverse) | | | | | | |
| | 9 × 3 × 2 turn | | 2 | 4.4 | 1.8e+4 | 0.122 | 24.4 |
| | (reverse) | | | | | | |
| Slope | 9 × 8 × 1 turn | 3.7 | 1 | 4.3 | 1.2e+4 | 0.017 | 1.7 |
| type | | | 2 | 8.9 | 2.5e+4 | 0.060 | 0.1 |
| | | | 3 | 13.9 | 3.9e+4 | 0.131 | 1.8 |
| | 12 × 8 × 1 | 5.0 | 2 | 10.1 | 2.1e+4 | 0.038 | 0.1 |
| | turn | | | | | | |

Even when a coolant flow path turns two times by being folded as in a conventional example, a difference in a heat transfer line density may be reduced from 36.2% to 7.4% and 24.4% as compared to a case where a coolant flow path turns one time. However, since space is needed to fold a coolant flow path, there is a limitation in reducing a difference in a heat transfer line density. As in an example of the present invention (a slope type), a difference in a heat transfer line density may be reduced to a value less than 2% by changing a height without folding a coolant flow path.

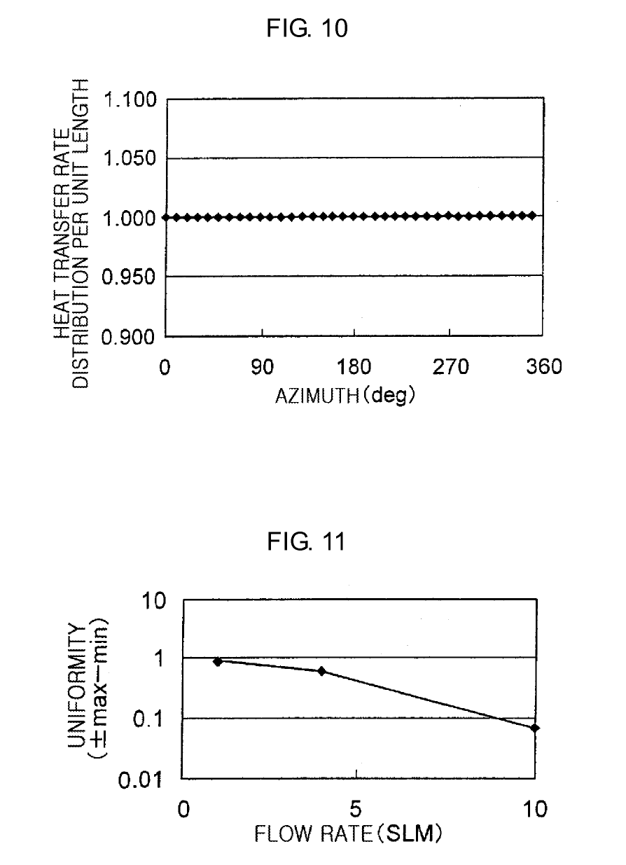

FIGS. 9 through 11 show results obtained after experimenting on optimization when a path length of a coolant flow path is defined as a third-degree expression. As shown in FIG. 9, a height of an inlet of a coolant flow path is 12 mm, and is reduced in a third-degree expression manner toward an outlet. A groove width is 8 mm. As shown in FIG. 10, when a flow rate of a coolant is 10.1 L/min and an amount of transferred heat is 2 kW, a difference in a heat transfer line density (heat transfer uniformity) may be reduced to ±0.06% or less. As shown in FIG. 11, when a flow rate of a coolant is equal to or less than 2 L/min, heat transfer uniformity is slightly reduced, and when a flow rate of a coolant is equal to or greater than 5 L/min, heat transfer uniformity may be reduced to a very small value.

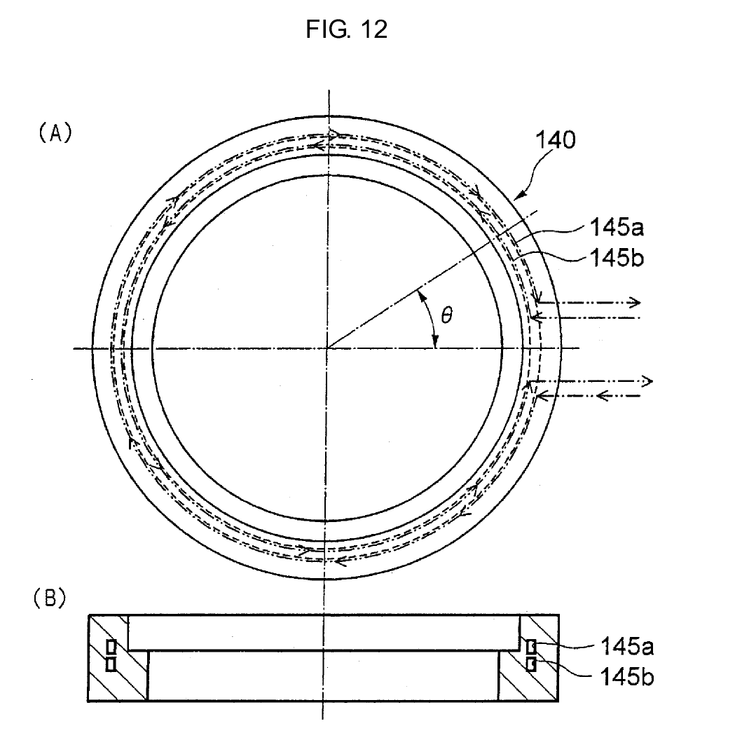

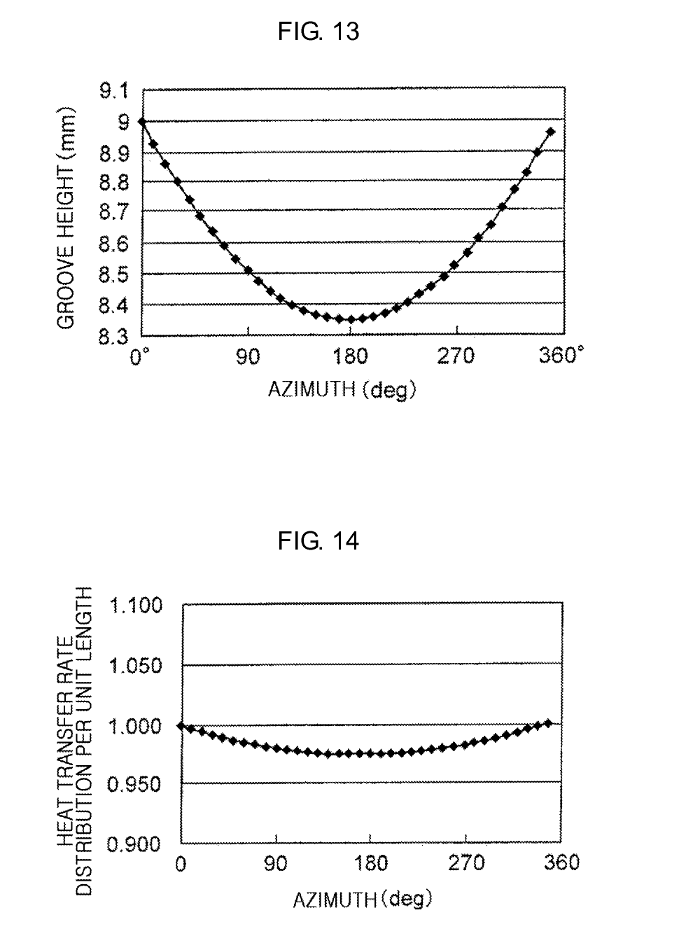

FIG. 12 shows the coolant flow path 145, which has two paths and includes first and second coolant flow paths 145a and 145b, formed in the upper plate 140 according to another embodiment of the present invention. The first and second coolant flow paths 145a and 145b are arranged in a vertical direction of the upper plate 140. An inlet and an outlet of each of the first and second coolant flow paths 145a and 145b respectively have azimuths of 0° and 360°. FIG. 13 shows a relationship between an azimuth and a height of each of the first and second coolant flow paths 145a and 145b. The height of each of the first and second coolant flow paths 145a and 145b is set to be gradually decreased until the azimuth reaches 180°, and to be gradually increased while the azimuth ranges from 180° to 360°. The reason why the height of each of the first and second coolant flow paths 145a and 145b is set in this way is as follows. As shown in FIG. 14 showing a comparative example, when a groove depth is constant, a portion having an azimuth of 180° has a least amount of transferred heat and an almost symmetric shape about 180° is obtained. In order to increase a heat transfer rate at the portion having the azimuth of 180° a groove depth is reduced and a flow velocity is increased. Also, sufficient heat uniformity is obtained with the help of a groove depth distribution having a substantially symmetric shape.

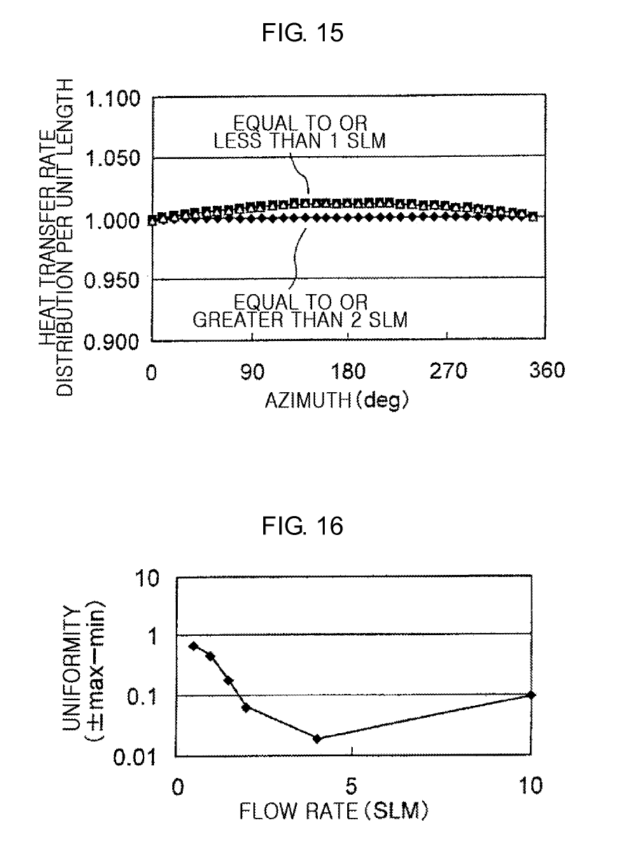

FIG. 14 shows a comparative example when the height of each of the first and second coolant flow paths 145a and 145b is constant. When a height of a coolant flow path is 9 mm, a width of the coolant flow path is 6 mm, a flow rate of a coolant is 9 L/min, and an amount of transferred heat is 2 kW, heat transfer uniformity was ±1.3%. However, by adjusting the height of each of the first and second coolant flow paths 145a and 145b, as shown in FIGS. 15 and 16, heat transfer uniformity was equal to or less than ±0.1% when a flow rate of a coolant is equal to or greater than 2 L/min, and heat transfer uniformity was equal to or less than ±0.6% when a flow rate of a coolant is equal to or less than 1 L/min.

Also, the present invention is not limited to the embodiments and various modifications may be made without departing from the scope of the present invention. For example, a coolant flow path of the present invention may be formed in a lower shower, and the lower shower may be cooled by flowing a gas such as an argon gas in the coolant flow path.

A conductive film may be integrally formed by plating or the like on a top surface and a bottom surface of a dielectric plate, the conductive film formed on the top surface may be used as a conductive plate which reflects a microwave, and the conductive film formed on the bottom surface may be used as a slot plate through which a microwave is transmitted.

This application claims the benefit of Japanese Patent Application No. 2009-146838 filed on Jun. 19, 2009.

1. A plasma processing apparatus comprising:
a processing container which is sealable and in which plasma processing is performed on an object;
a holding stage which is disposed in the processing container and holds the object;
a dielectric window which is disposed on a ceiling portion of the processing container and seals the processing container; and
a microwave antenna which is disposed on the dielectric window and radiates a microwave into the processing container,
wherein a coolant flow path for cooling the dielectric window is provided in a side wall of the processing container,
a coolant flows in a liquid or gaseous state in the coolant flow path without phase transition, and
at least a portion of the coolant flow path extending in a circumferential direction of the side wall has a cross-sectional area decreased toward downstream from upstream.

2. A plasma processing apparatus comprising:
a processing container which is sealable and in which plasma processing is performed on an object;
a holding stage which is disposed in the processing container and holds the object;
a dielectric window which is disposed on a ceiling portion of the processing container and seals the processing container;
a microwave antenna which is disposed on the dielectric window and radiates a microwave into the processing container; and
a cooling plate which is disposed on the microwave antenna and comprises a coolant flow path for cooling the microwave antenna,
wherein a coolant flows in a liquid or gaseous state in the cooling plate without phase transition, and
at least a portion of the coolant flow path extending in a circumferential direction of the cooling plate has a cross-sectional area decreased toward downstream from upstream.

3. The plasma processing apparatus of claim 1, wherein the coolant flow path has a rectangular cross-sectional shape, and
the coolant flow path has a constant width and a height decreased toward the downstream from the upstream.

4. The plasma processing apparatus of claim 3, wherein the height of the coolant flow path is defined as an nth-degree expression with respect to a path length of the coolant flow path, where n is a natural number.

5. The plasma processing apparatus of claim 3, wherein the coolant flow path is formed in the side wall of the processing container to have a spiral shape turning one or more times, and
a height of a portion of the cooling flow path, turning at least one time, is decreased toward the downstream from the upstream.

6. The plasma processing apparatus of claim 5, wherein the coolant flow path is formed in the side wall of the processing container to have a spiral shape turning two or more times,
while turning one time, a height of the coolant flow path is decreased toward the downstream from the upstream, and
at a connected portion between a portion of the coolant flow path, turning one time, and another portion of the coolant flow path, turning another one time, a height of the coolant flow path returns to an original height.

7. The plasma processing apparatus of claim 3, wherein the coolant flow path comprises a plurality of coolant flow paths which are arranged in a vertical direction and each of which is formed in the side wall of the processing container to have an annular shape turning one time, and
a height of each coolant flow path having an annular shape turning one time is decreased toward the downstream from the upstream.

8. The plasma processing apparatus of claim 3, wherein the coolant flow path comprises first and second coolant flow paths extending in the circumferential direction of the side wall of the processing container,
directions in which the coolant flows in the first and second coolant flow paths are opposite to each other, and
a height of the first coolant flow path is decreased toward the downstream from the upstream and then is increased again, and a height of the second coolant flow path is decreased toward the downstream from the upstream and then is increased again.

9. The plasma processing apparatus of claim 2, wherein the coolant flow path has a rectangular cross-sectional shape, and
the coolant flow path has a constant width and a height decreased toward the downstream from the upstream, and
wherein the coolant flow path is formed in the cooling plate to have a spiral shape turning one or more times, and
a height of a portion of the coolant flow path, turning at least one time, is decreased toward the downstream from the upstream.

10. The plasma processing apparatus of claim 1, wherein the coolant is a fluorine-based liquid.

11. A plasma processing apparatus comprising:
a processing container which is sealable and in which plasma processing is performed on an object;
a holding stage which is disposed in the processing container and holds the object;
a plasma exciting unit which excites plasma in the processing container; and
a coolant flow path which cools a member heated by the plasma,
wherein a coolant flows in a liquid or gaseous state in the coolant flow path without phase transition, and
at least a portion of the coolant flow path has a cross-sectional area decreased toward downstream from upstream.

12. A cooling device for a plasma processing apparatus which is provided in the plasma processing apparatus for performing plasma processing on an object and cools a member heated by plasma, the cooling device comprising a coolant flow path in which a coolant flows in a liquid or gaseous state without phase transition,
wherein at least a portion of the coolant flow path has a cross-sectional area decreased toward downstream from upstream.
